(19) United States
(12) Patent Application Publication
(10) Pub. No.: US 2015/0321621 A1
(43) Pub. Date: Nov. 12, 2015

(54) VEHICLE VISION SYSTEM CAMERA WITH GRAPHENE LENS

(71) Applicant: MAGNA ELECTRONICS INC., Auburn Hills, MI (US)

(72) Inventors: Christopher L. Van Dan Elzen, Rochester, MI (US); Adam T. Keever, Muncie, IN (US)

(21) Appl. No.: 14/705,077

(22) Filed: May 6, 2015

Related U.S. Application Data
(60) Provisional application No. 61/991,809, filed on May 12, 2014.

(51) Int. Cl. B60R 11/04; H05K 1/09; B60R 1/00; H04N 5/225; G02B 13/00; H05K 1/03; H05K 1/02

(52) U.S. Cl. CPC B60R 11/04; H05K 1/0306; H05K 1/0313; H05K 1/09; H05K 1/0201; H04N 5/2254; G02B 13/0015; B60R 1/00; H05K 2201/0323; H05K 2201/0317; H05K 2201/0108; B60R 2300/10

(57) ABSTRACT

A vision system of a vehicle includes a camera disposed at a vehicle and having a field of view exterior of the vehicle. The camera includes a pixelated imaging array having a plurality of photosensing elements. The camera includes a lens having at least one optic element. The at least one optic element includes graphene or the at least one optic element has a graphene coating or trace at a surface thereof or the at least one optic element has a transparent shield disposed thereat and having graphene or a graphene coating or trace or the at least one optic element has a replaceable protective film or element disposed thereat and having graphene or a graphene coating or trace. Electrical leads are used to energize or power graphene traces in order to limit icing or fogging of the camera lens.

### CROSS REFERENCE TO RELATED APPLICATION

The present application claims the filing benefits of U.S. provisional application Ser. No. 61/991,809, filed May 12, 2014, which is hereby incorporated herein by reference in its entirety.

### FIELD OF THE INVENTION

The present invention relates generally to a vehicle vision system for a vehicle and, more particularly, to a vehicle vision system that utilizes one or more cameras at a vehicle.

### BACKGROUND OF THE INVENTION

Use of imaging sensors in vehicle imaging systems is common and known. Examples of such known systems are described in U.S. Pat. Nos. 5,949,331; 5,670,935 and/or 5,550,677, which are hereby incorporated herein by reference in their entireties.

### SUMMARY OF THE INVENTION

The present invention provides a vision system or imaging system for a vehicle that utilizes one or more cameras (preferably one or more CMOS cameras) to capture image data representative of images exterior of the vehicle. The camera includes an imager or imaging array sensor and a lens, with the lens comprising at least one optic element for focusing images at the imager or imaging array sensor. The lens optic, such as an outermost lens optic may comprise a graphene material, thus providing an outer optic with enhanced strength and resistance to scratching and the like. Optionally, the graphene material may be electrically energizable or powered to provide a defogging function at the lens.

Optionally, the camera lens optic may be manufactured or assembled with electrical leads on or at its surface, and a replaceable tempered glass or polymer film containing a graphene circuit or trace terminating at the film surface with exposed leads may be affixed in such a manner that the exposed leads of the film electrically connect to the electrical leads of the lens optic, such that the film is energizable to provide a defogging function at the protective film surface and the lens optic. Optionally, the camera lens optic may be behind a glass or polymer shield with electric leads on its surface, and a replaceable tempered glass or polymer film comprising a graphene circuit terminating at the film surface with exposed leads may be affixed in such a manner that the exposed leads of the film electrically connect to the electrical leads of the shield, such that the film is energizable to provide a defogging function at the protective film surface and at the shield at the lens optic.

Optionally, aspects of the lens optics of the present invention may be used at a window of a vehicle, such as at a windshield of the vehicle, or may be used at a mirror reflective element, such as for an exterior side rearview mirror of the vehicle or the like. Optionally, the window or reflective element may be manufactured or assembled with electrical leads at its surface, and a replaceable tempered glass or polymer film or element comprising a graphene circuit terminating at the film surface with exposed leads may be affixed in such a manner that the exposed leads of the film electrically connect to the electrical leads of the window or reflective element, such that the film or element is energizable to provide a defogging function at the protective film surface.

These and other objects, advantages, purposes and features of the present invention will become apparent upon review of the following specification in conjunction with the drawings.

### BRIEF DESCRIPTION OF THE DRAWINGS

FIG. 1 is a plan view of a vehicle with a vision system that incorporates cameras in accordance with the present invention;

FIG. 2 is a side view of a lens optic of a camera of FIG. 1, shown with a graphene coating in accordance with the present invention;

FIG. 3 is a perspective view of a vehicle having a rear camera in accordance with the present invention;

FIG. 4 is a perspective view of the camera of the vehicle of FIG. 3, shown with a protective film affixed to the lens optic of the camera with a graphene circuit established thereat;

FIG. 4A is a plan view of the protective film (such as tempered glass or polymer or the like) with embedded electrical leads and a graphene circuit or trace established thereat;

FIG. 4B is a perspective view of the camera of FIG. 4, shown with electric leads at a surface of the lens optic of the camera, whereby the replaceable protective film of FIG. 4A, having a graphene circuit and electric leads, is energizable when disposed at the shielding to provide a defogging function at the camera lens;

FIG. 5 is a perspective view of another camera having a glass or polymer shielding at a lens optic of the camera, with the shielding having a protective film disposed thereat, with the protective film having embedded electric leads and a graphene circuit or trace in accordance with the present invention;

FIG. 5A is a view of the protective film, such as a tempered glass film or polymer film or the like, of FIG. 5, shown with embedded electric leads and graphene circuit or trace;

FIG. 5B is a perspective view of the camera of FIG. 5, shown with electric leads at a surface of the glass or polymer shielding at the lens optic of the camera, whereby the replaceable protective film of FIG. 5A, having the graphene circuit and electric leads, is energizable when disposed at the shielding to provide a defogging function at the camera lens;

FIG. 6 is a perspective view of a side view mirror of a vehicle, shown with a replaceable protective film disposed at a surface of the reflective element, with the protective film having a graphene circuit and electric leads in accordance with the present invention;

FIG. 6A is a view of the protective film, such as a tempered glass film or polymer film or the like, for the mirror of FIG. 6, shown with embedded electric leads and graphene circuit or trace;

FIG. 6B is a perspective view of the mirror of FIG. 6, shown with electric leads at a surface of the mirror reflective element, whereby the replaceable protective film of FIG. 6A, having the graphene circuit and electric leads, is energizable when disposed at the reflective element to provide a defogging function;

FIG. 7 is a perspective view of a vehicle having a window having a protective film disposed thereat, with the protective film having a graphene circuit and electric leads in accordance with the present invention, with the protective film covering a small area of the window or optionally the entire window;

FIG. 7A is a view of the protective film, such as a tempered glass film or polymer film or the like, for the window of FIG. 7, shown with embedded electric leads and graphene circuit or trace; and

FIG. 7B is a view of a portion of the window of FIG. 7, shown with electric leads at a surface of the window, whereby the replaceable protective film of FIG. 7A, having the graphene circuit and electric leads, is energizable when disposed at the window to provide a defogging function.

### DESCRIPTION OF THE PREFERRED EMBODIMENTS

A vehicle vision system and/or driver assist system and/or object detection system and/or alert system operates to capture images exterior of the vehicle and may process the captured image data to display images and to detect objects at or near the vehicle and in the predicted path of the vehicle, such as to assist a driver of the vehicle in maneuvering the vehicle in a rearward direction. The vision system includes an image processor or image processing system that is operable to receive image data from one or more cameras and provide an output to a display device for displaying images representative of the captured image data. Optionally, the vision system may provide a top down or bird's eye or surround view display and may provide a displayed image that is representative of the subject vehicle, and optionally with the displayed image being customized to at least partially correspond to the actual subject vehicle.

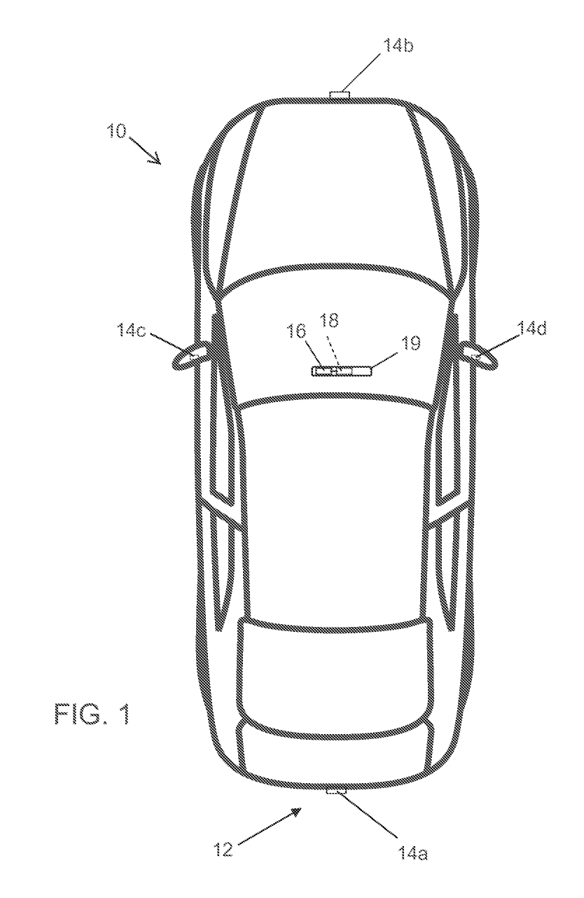

Referring now to the drawings and the illustrative embodiments depicted therein, a vehicle 10 includes an imaging system or vision system 12 that includes at least one exterior facing imaging sensor or camera, such as a rearward facing imaging sensor or camera 14a (and the system may optionally include multiple exterior facing imaging sensors or cameras, such as a forwardly facing camera 14b at the front (or at the windshield) of the vehicle, and a sidewardly/rearwardly facing camera 14c, 14d at respective sides of the vehicle), which captures images exterior of the vehicle, with the camera having a lens for focusing images at or onto an imaging array or imaging plane or imager of the camera (FIG. 1). The vision system 12 includes a control or electronic control unit (ECU) or processor 18 that is operable to process image data captured by the cameras and may provide displayed images at a display device 16 for viewing by the driver of the vehicle (although shown in FIG. 1 as being part of or incorporated in or at an interior rearview mirror assembly 19 of the vehicle, the control and/or the display device may be disposed elsewhere at or in the vehicle). The data transfer or signal communication from the camera to the ECU may comprise any suitable data or communication link, such as a vehicle network bus or the like of the equipped vehicle.

Vehicles may be equipped with at least one or multiple cameras, such as for generating surround view and rear view panorama vision such as described in U.S. provisional application Ser. No. 61/120,014, filed Feb. 24, 2015, which is hereby incorporated herein by reference in its entirety. The lens or film or element or shield of the present invention may be applied to at least one of the cameras (or all of the cameras), such as a lens of a camera that is at an exterior portion of the vehicle where the lens may be exposed to the exterior elements, comprises a graphene material. Graphene is an allotrope of carbon in the form of a two-dimensional, atomic-scale, hexagonal lattice in which one atom forms each vertex. Graphene is a zero-gap semiconductor, is electrically conductive and is highly thermally conductive.

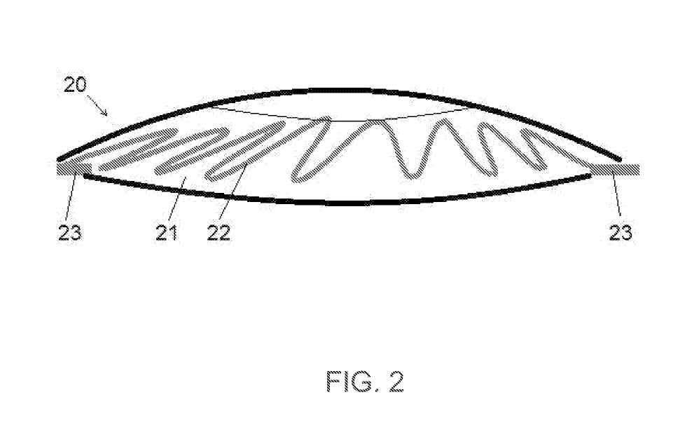

For example, the outermost lens optic may comprise a graphene material so as to be a substantially transparent and strong optic element. Optionally, and such as shown in FIG. 2, the lens 20 may have an outer surface 21 (which may be exposed to the elements) with an electrically conductive graphene heating trace or structure or thin film coating 22 disposed at or established at the outer surface 21 that, when a voltage is applied and electrical current is passed through the graphene heating trace or structure or coating, the lens 20 is heated. The graphene heating trace 22 may be electrically connected at contacts or contacting structure 23 that are operable to power the graphene heating trace to heat the outer optic 20 (or optionally a protective film or transparent shielding at the optic, as discussed below), such as to melt ice or snow at the lens (or film or shielding) or to defog or defrost the lens (or film or shielding).

Thus, a surface of a camera optic (or other element, such as a window or mirror reflective element as discussed below) or a protective film or element (such as a tempered glass film or sheet or layer or a polymer film or sheet or layer) may have a graphene trace to provide a defogging function. The protective film or layer or element may have embedded electric leads and a graphene trace, and may be applied easily and replaced if damaged. Such a protective film may be used in any suitable application, and may mate with various glass substrates (such as any or all windows of a vehicle) or mirror substrates (such as for any or all exterior mirrors of a vehicle) or optics (such as for imaging sensors or cameras of a vision system of a vehicle) that are manufactured or assembled with opposing electric leads.

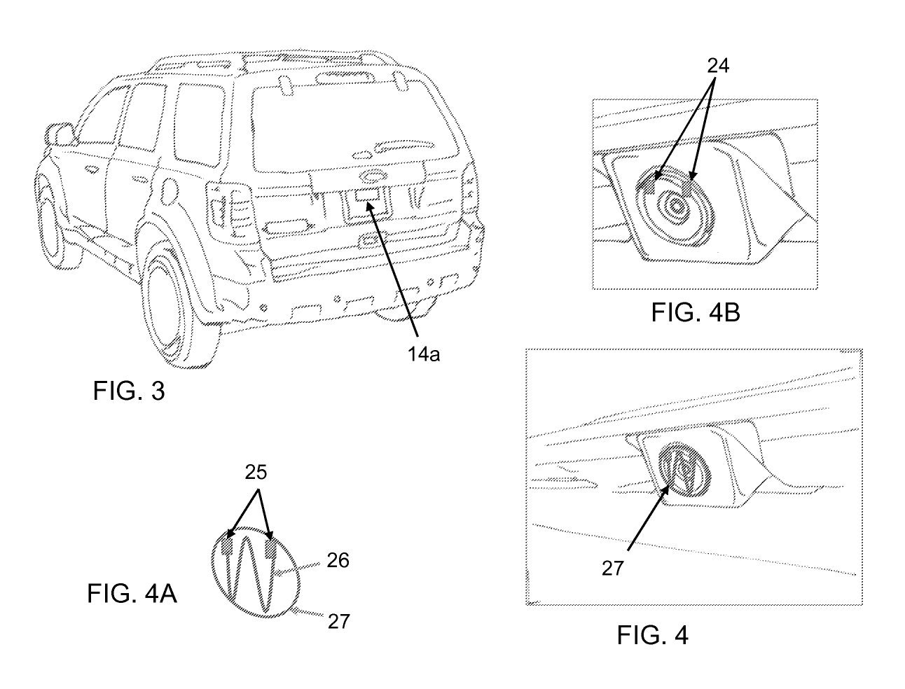

Optionally, and such as shown in FIGS. 4, 4A and 4B, a protective film 27 may be provided with a graphene trace 26 and electrical leads 25 embedded therein or established thereat, while the lens optic of the camera (such as rear camera 14a of FIGS. 1 and 3) has electrical leads 24 disposed at the lens optic. The protective film 27 is affixed to the lens (and may be a replaceable protective film that may be removed and replaced if damaged) such that its electrical leads or contacts 25 are electrically connected to the electrical leads 24 at the lens optic, such that the graphene circuit is energizable via circuitry electrically connected to the leads 24 at the lens optic when the protective film 27 is affixed to or disposed at the lens of the camera, and provides a defogging function at the lens of the camera.

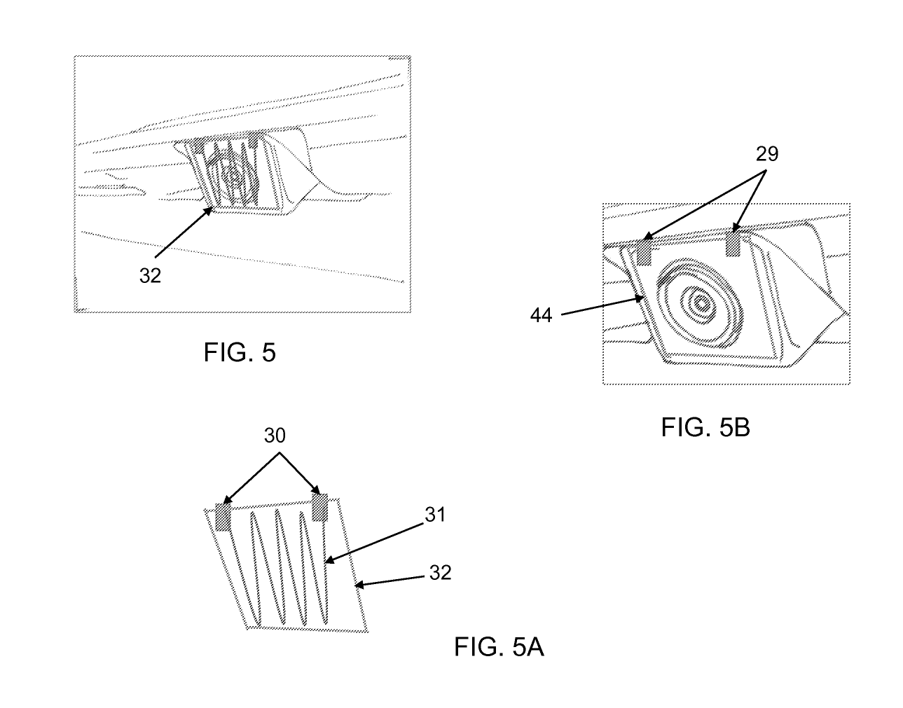

Optionally, and such as shown in FIGS. 5, 5A and 5B, a camera may have a glass or polymer shielding 44 disposed at and in front of the lens optics of the camera, and the shielding may have electrical leads or contacts 29 established thereat (and electrically connected to a power source or circuitry of the camera and/or vehicle). A replaceable protective film 32, having a graphene trace 31 and electrical leads 30 embedded therein or established thereat, is attachable at the shielding (and may be a replaceable protective film that may be removed and replaced if damaged). Thus, the graphene circuit is energizable via circuitry electrically connected to the leads 29 at the shielding 44 when the protective film 32 is affixed to or disposed at the shielding at the lens of the camera, and provides a defogging function at the lens of the camera.

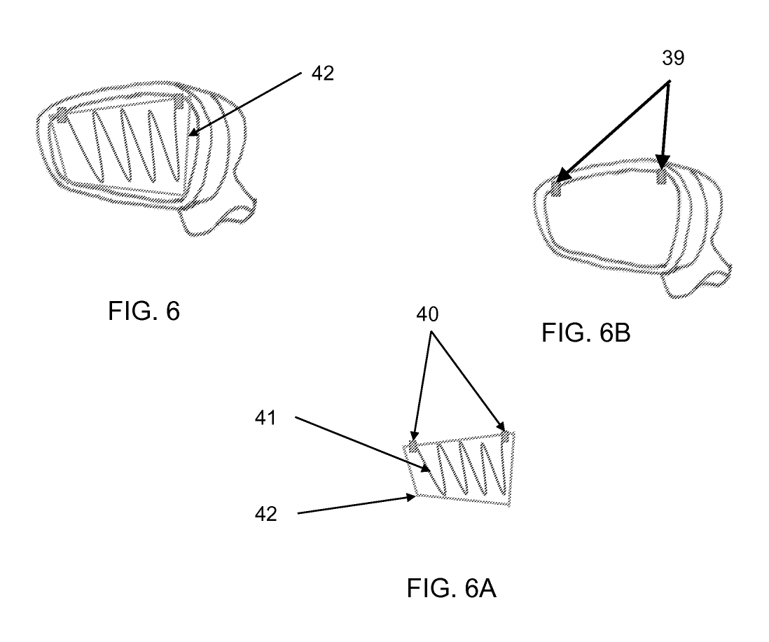

Optionally, and such as shown in FIGS. 6, 6A and 6B, an exterior rearview mirror assembly of a vehicle may have a protective film 42 disposed at the reflective element of the mirror. The reflective element of the mirror has electrical leads or contacts 39 established thereat (and electrically connected to a power source or circuitry of the mirror and/or vehicle). A replaceable protective film 42, having a graphene trace 42 and electrical leads 40 embedded therein or established thereat, is attachable at the reflective element (and may be a replaceable protective film that may be removed and replaced if damaged). Thus, the graphene circuit is energizable via circuitry electrically connected to the leads 39 at the reflective element when the protective film 42 is affixed to or disposed at the mirror reflective element, and provides a defogging function at the mirror reflective element.

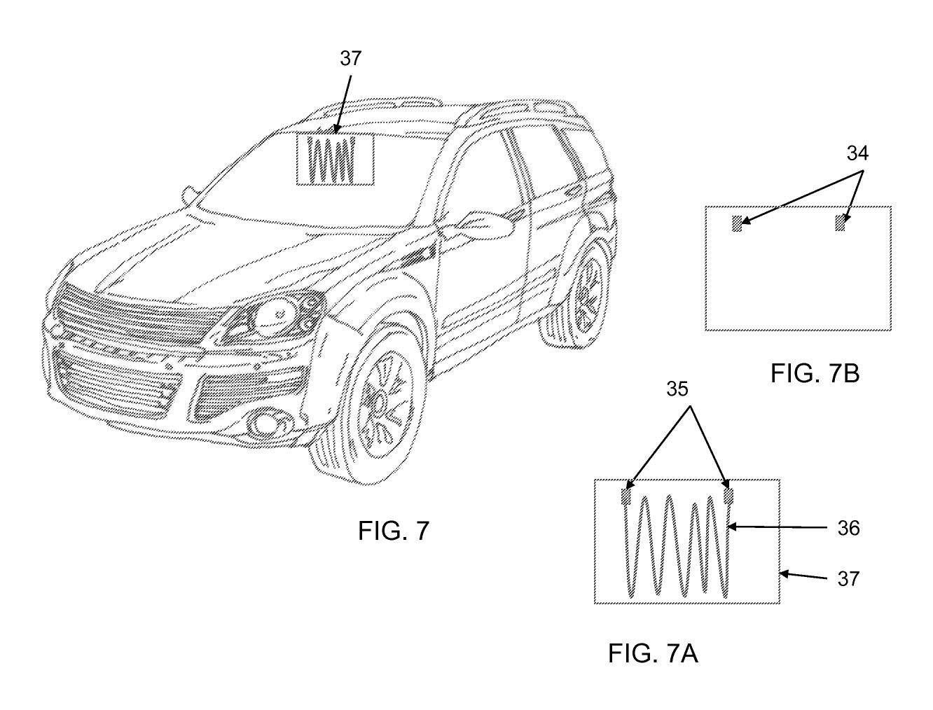

Optionally, and such as shown in FIGS. 7, 7A and 7B, a window of a vehicle (such as the vehicle windshield as shown in FIG. 7) may have a protective film 37 disposed thereat or affixed thereto. The window has electrical leads or contacts 34 established thereat (and electrically connected to a power source or circuitry of the vehicle). A replaceable protective film 37, having a graphene trace 36 and electrical leads 35 embedded therein or established thereat, is attachable at the window (and may be a replaceable protective film or element that may be removed and replaced if damaged). Thus, the graphene circuit is energizable via circuitry electrically connected to the leads 34 at the window when the protective film 37 is affixed to or disposed at the vehicle window, and provides a defogging function at the vehicle window.

Graphene is a relatively new material that has unique characteristics that allow for many uses. Graphene is a two dimensional allotrope of carbon that has excellent electrical conductivity. The structure of the Graphene makes it near transparent. Because of its ability to be transparent or transmissive of light, graphene may be suitable for use as the material of a lens optic or as a coating or trace at a surface of a glass or plastic lens optic.

Optionally, the lens at the imager may be made from graphene, to provide enhanced strength of the lens optic so that the outer lens optic may withstand impact and contact with rocks, salt, dirt and/or the like, at the exterior environment. Optionally, the lens optic may be formed of graphene, or a plastic or glass lens optic may be coated (such as at its exterior surface) with graphene.

Optionally, graphene may be applied at the outer lens exterior exposed surface, or at a transparent shielding, or replaceable protective film or element to protect the lens against scratches and dirt. Additionally, the graphene may be structured in a manner that it has a controlled electrical resistance, and there may be contact areas (such as shown in FIGS. 2, 4, 5, 6 and 7) at the sides of the lens, shield, or film to apply an electrical current. The electrical power may cause the graphene material to heat so as to defrost or defog the lens, shield, or film or melt ice or snow flakes at or on the lens, shield, or film.

Optionally, the graphene material may be used at or on a glass or plastic window of a vehicle or at or on a replaceable protective film or element disposed at a window of a vehicle. For example, a graphene coating may be applied at a vehicle windshield for defrosting of the glass windshield, or a replaceable protective film or element having a graphene trace or coating may be affixed on the windshield, such as at or near a forward facing camera or imager (such as a camera of the types described in International Publication Nos. WO 2013/123161 and/or WO 2013/019795, and/or U.S. Pat. Nos. 8,256,821; 7,480,149; 7,289,037; 7,004,593; 6,824,281; 6,690,268; 6,445,287; 6,428,172; 6,420,975; 6,326,613; 6,278,377; 6,243,003; 6,250,148; 6,172,613 and/or 6,087,953, and/or U.S. Publication Nos. US-2009-0295181 and/or US-2014-0226012, and/or U.S. provisional application Ser. No. 61/990,927, filed May 9, 2014, which are all hereby incorporated herein by reference in their entireties) or the like. Optionally, the graphene material may be layered into the auto glass or mirrors or replaceable protective films or elements to facilitate its defrosting.

The passing of an electrical current through a layered network of graphene at or near the outer surface of a vehicular glass window, windshield, mirror, or replaceable protective film or element may provide for a rapid defrosting of the vehicle window, windshield, mirror, or replaceable protective film or element. The use of such a heatable graphene coating may limit or prevent the build-up of ice on the windows and/or mirrors while the driver is driving the vehicle.

Thus, the present invention provides for use of graphene material at or on or in a lens optic of a lens assembly of a vehicle camera, such as for a lens that has an outer optic at least partially exposed to the environment at an exterior region of a vehicle or use of graphene material at or on or in a transparent shield for said the lens optic. The graphene provides enhanced strength to the optic and/or provides a heating element to defog or defrost the optic. Optionally, the graphene may be applicable at or in a glass window or mirror reflective element of a vehicle or a replaceable protective film or element affixed to a glass window or mirror reflective element, such as at or in or on at least a portion of a windshield or mirror reflective element of the vehicle, to provide enhanced defogging or defrosting of the windshield or mirror portion when the graphene coating or element or portion is energized.

The camera or sensor may comprise any suitable camera or sensor. Optionally, the camera may comprise a “smart camera” that includes the imaging sensor array and associated circuitry and image processing circuitry and electrical connectors and the like as part of a camera module, such as by utilizing aspects of the vision systems described in International Publication Nos. WO 2013/081984 and/or WO 2013/081985, which are hereby incorporated herein by reference in their entireties.

The system includes an image processor operable to process image data captured by the camera or cameras, such as for detecting objects or other vehicles or pedestrians or the like in the field of view of one or more of the cameras. For example, the image processor may comprise an EyeQ2 or EyeQ3 image processing chip available from Mobileye Vision Technologies Ltd. of Jerusalem, Israel, and may include object detection software (such as the types described in U.S. Pat. Nos. 7,855,755; 7,720,580 and/or 7,038,577, which are hereby incorporated herein by reference in their entireties), and may analyze image data to detect vehicles and/or other objects. Responsive to such image processing, and when an object or other vehicle is detected, the system may generate an alert to the driver of the vehicle and/or may generate an overlay at the displayed image to highlight or enhance display of the detected object or vehicle, in order to enhance the driver's awareness of the detected object or vehicle or hazardous condition during a driving maneuver of the equipped vehicle.

The vehicle may include any type of sensor or sensors, such as imaging sensors or radar sensors or lidar sensors or ladar sensors or ultrasonic sensors or the like. The imaging sensor or camera may capture image data for image processing and may comprise any suitable camera or sensing device, such as, for example, a two dimensional array of a plurality of photosensor elements arranged in at least 640 columns and 480 rows (at least a 640×480 imaging array, such as a megapixel imaging array or the like), with a respective lens focusing images onto respective portions of the array. The photosensor array may comprise a plurality of photosensor elements arranged in a photosensor array having rows and columns. Preferably, the imaging array has at least 300,000 photosensor elements or pixels, more preferably at least 500,000 photosensor elements or pixels and more preferably at least 1 million photosensor elements or pixels. The imaging array may capture color image data, such as via spectral filtering at the array, such as via an RGB (red, green and blue) filter or via a red/red complement filter or such as via an RCC (red, clear, clear) filter or the like. The logic and control circuit of the imaging sensor may function in any known manner, and the image processing and algorithmic processing may comprise any suitable means for processing the images and/or image data.

For example, the vision system and/or processing and/or camera and/or circuitry may utilize aspects described in U.S. Pat. Nos. 7,005,974; 5,760,962; 5,877,897; 5,796,094; 5,949,331; 6,222,447; 6,302,545; 6,396,397; 6,498,620; 6,523,964; 6,611,202; 6,201,642; 6,690,268; 6,717,610; 6,757,109; 6,802,617; 6,806,452; 6,822,563; 6,891,563; 6,946,978; 7,859,565; 5,550,677; 5,670,935; 6,636,258; 7,145,519; 7,161,616; 7,230,640; 7,248,283; 7,295,229; 7,301,466; 7,592,928; 7,881,496; 7,720,580; 7,038,577; 6,882,287; 5,929,786 and/or 5,786,772, and/or International Publication Nos. WO 2011/028686; WO 2010/099416; WO 2012/061567; WO 2012/068331; WO 2012/075250; WO 2012/103193; WO 2012/0116043; WO 2012/0145313; WO 2012/0145501; WO 2012/145818; WO 2012/145822; WO 2012/1 58167; WO 2012/075250; WO 2012/0116043; WO 2012/0145501; WO 2012/154919; WO 2013/019707; WO 2013/016409; WO 2013/019795; WO 2013/067083; WO 2013/070539; WO 2013/043661; WO 2013/048994; WO 2013/063014, WO 2013/081984; WO 2013/081985; WO 2013/074604; WO 2013/086249; WO 2013/103548; WO 2013/109869; WO 2013/123161; WO 2013/126715; WO 2013/043661 and/or WO 2013/158592, which are all hereby incorporated herein by reference in their entireties. The system may communicate with other communication systems via any suitable means, such as by utilizing aspects of the systems described in International Publication Nos. WO/2010/144900; WO 2013/043661 and/or WO 2013/081985, and/or U.S. Publication No. US-2012-0062743, which are hereby incorporated herein by reference in their entireties.

The imaging device and control and image processor and any associated illumination source, if applicable, may comprise any suitable components, and may utilize aspects of the cameras and vision systems described in U.S. Pat. Nos. 5,550,677; 5,877,897; 6,498,620; 5,670,935; 5,796,094; 6,396,397; 6,806,452; 6,690,268; 7,005,974; 7,937,667; 7,123,168; 7,004,606; 6,946,978; 7,038,577; 6,353,392; 6,320,176; 6,313,454 and/or 6,824,281, and/or International Publication Nos. WO 2010/099416; WO 2011/028686 and/or WO 2013/016409, and/or U.S. Pat. Publication Nos. US 2010-0020170 and/or US-2013-0002873, which are all hereby incorporated herein by reference in their entireties. The camera or cameras may comprise any suitable cameras or imaging sensors or camera modules, and may utilize aspects of the cameras or sensors described in U.S. Publication No. US-2009-0244361 and/or U.S. Pat. Nos. 8,542,451; 7,965,336 and/or 7,480,149, which are hereby incorporated herein by reference in their entireties. The imaging array sensor may comprise any suitable sensor, and may utilize various imaging sensors or imaging array sensors or cameras or the like, such as a CMOS imaging array sensor, a CCD sensor or other sensors or the like, such as the types described in U.S. Pat. Nos. 5,550,677; 5,670,935; 5,760,962; 5,715,093; 5,877,897; 6,922,292; 6,757,109; 6,717,610; 6,590,719; 6,201,642; 6,498,620; 5,796,094; 6,097,023; 6,320,176; 6,559,435; 6,831,261; 6,806,452; 6,396,397; 6,822,563; 6,946,978; 7,339,149; 7,038,577; 7,004,606; 7,720,580 and/or 7,965,336, and/or International Publication Nos. WO/2009/036176 and/or WO/2009/046268, which are all hereby incorporated herein by reference in their entireties.

The camera module and circuit chip or board and imaging sensor may be implemented and operated in connection with various vehicular vision-based systems, and/or may be operable utilizing the principles of such other vehicular systems, such as a vehicle headlamp control system, such as the type disclosed in U.S. Pat. Nos. 5,796,094; 6,097,023; 6,320,176; 6,559,435; 6,831,261; 7,004,606; 7,339,149 and/or 7,526,103, which are all hereby incorporated herein by reference in their entireties, a rain sensor, such as the types disclosed in commonly assigned U.S. Pat. Nos. 6,353,392; 6,313,454; 6,320,176 and/or 7,480,149, which are hereby incorporated herein by reference in their entireties, a vehicle vision system, such as a forwardly, sidewardly or rearwardly directed vehicle vision system utilizing principles disclosed in U.S. Pat. Nos. 5,550,677; 5,670,935; 5,760,962; 5,877,897; 5,949,331; 6,222,447; 6,302,545; 6,396,397; 6,498,620; 6,523,964; 6,611,202; 6,201,642; 6,690,268; 6,717,610; 6,757,109; 6,802,617; 6,806,452; 6,822,563; 6,891,563; 6,946,978 and/or 7,859,565, which are all hereby incorporated herein by reference in their entireties, a trailer hitching aid or tow check system, such as the type disclosed in U.S. Pat. No. 7,005,974, which is hereby incorporated herein by reference in its entirety, a reverse or sideward imaging system, such as for a lane change assistance system or lane departure warning system or for a blind spot or object detection system, such as imaging or detection systems of the types disclosed in U.S. Pat. Nos. 7,881,496; 7,720,580; 7,038,577; 5,929,786 and/or 5,786,772, which are hereby incorporated herein by reference in their entireties, a video device for internal cabin surveillance and/or video telephone function, such as disclosed in U.S. Pat. Nos. 5,760,962; 5,877,897; 6,690,268 and/or 7,370,983, and/or U.S. Publication No. US-2006-0050018, which are hereby incorporated herein by reference in their entireties, a traffic sign recognition system, a system for determining a distance to a leading or trailing vehicle or object, such as a system utilizing the principles disclosed in U.S. Pat. Nos. 6,396,397 and/or 7,123,168, which are hereby incorporated herein by reference in their entireties, and/or the like.

Optionally, the circuit board or chip may include circuitry for the imaging array sensor and or other electronic accessories or features, such as by utilizing compass-on-a-chip or EC driver-on-a-chip technology and aspects such as described in U.S. Pat. Nos. 7,255,451 and/or 7,480,149, and/or U.S. Publication Nos. US-2010-0097469 and/or US-2006-0061008, which are hereby incorporated herein by reference in their entireties.

Optionally, the vision system may include a display for displaying images captured by one or more of the imaging sensors for viewing by the driver of the vehicle while the driver is normally operating the vehicle. Optionally, for example, the vision system may include a video display device disposed at or in the interior rearview mirror assembly of the vehicle, such as by utilizing aspects of the video mirror display systems described in U.S. Pat. No. 6,690,268 and/or U.S. Publication No. US-2012-0162427, which are hereby incorporated herein by reference in their entireties. The video mirror display may comprise any suitable devices and systems and optionally may utilize aspects of the compass display systems described in U.S. Pat. Nos. 7,370,983; 7,329,013; 7,308,341; 7,289,037; 7,249,860; 7,004,593; 4,546,551; 5,699,044; 4,953,305; 5,576,687; 5,632,092; 5,677,851; 5,708,410; 5,737,226; 5,802,727; 5,878,370; 6,087,953; 6,173,508; 6,222,460; 6,513,252 and/or 6,642,851, and/or European patent application, published Oct. 11, 2000 under Publication No. EP 0 1043566, and/or U.S. Publication No. US-2006-0061008, which are all hereby incorporated herein by reference in their entireties. Optionally, the video mirror display screen or device may be operable to display images captured by a rearward viewing camera of the vehicle during a reversing maneuver of the vehicle (such as responsive to the vehicle gear actuator being placed in a reverse gear position or the like) to assist the driver in backing up the vehicle, and optionally may be operable to display the compass heading or directional heading character or icon when the vehicle is not undertaking a reversing maneuver, such as when the vehicle is being driven in a forward direction along a road (such as by utilizing aspects of the display system described in International Publication No. WO 2012/051500, which is hereby incorporated herein by reference in its entirety).

Optionally, the vision system (utilizing the forward facing camera and a rearward facing camera and other cameras disposed at the vehicle with exterior fields of view) may be part of or may provide a display of a top-down view or birds-eye view system of the vehicle or a surround view at the vehicle, such as by utilizing aspects of the vision systems described in International Publication Nos. WO 2010/099416; WO 2011/028686; WO 2012/075250; WO 2013/019795; WO 2012/075250; WO 2012/145822; WO 2013/081985; WO 2013/086249 and/or WO 2013/109869, and/or U.S. Publication No. US-2012-0162427, which are hereby incorporated herein by reference in their entireties.

Optionally, a video mirror display may be disposed rearward of and behind the reflective element assembly and may comprise a display such as the types disclosed in U.S. Pat. Nos. 5,530,240; 6,329,925; 7,855,755; 7,626,749; 7,581,859; 7,446,650; 7,370,983; 7,338,177; 7,274,501; 7,255,451; 7,195,381; 7,184,190; 5,668,663; 5,724,187 and/or 6,690,268, and/or in U.S. Publication Nos. US-2006-0061008 and/or US-2006-0050018, which are all hereby incorporated herein by reference in their entireties. The display is viewable through the reflective element when the display is activated to display information. The display element may be any type of display element, such as a vacuum fluorescent (VF) display element, a light emitting diode (LED) display element, such as an organic light emitting diode (OLED) or an inorganic light emitting diode, an electroluminescent (EL) display element, a liquid crystal display (LCD) element, a video screen display element or backlit thin film transistor (TFT) display element or the like, and may be operable to display various information (as discrete characters, icons or the like, or in a multi-pixel manner) to the driver of the vehicle, such as passenger side inflatable restraint (PSIR) information, tire pressure status, and/or the like. The mirror assembly and/or display may utilize aspects described in U.S. Pat. Nos. 7,184,190; 7,255,451; 7,446,924 and/or 7,338,177, which are all hereby incorporated herein by reference in their entireties. The thicknesses and materials of the coatings on the substrates of the reflective element may be selected to provide a desired color or tint to the mirror reflective element, such as a blue colored reflector, such as is known in the art and such as described in U.S. Pat. Nos. 5,910,854; 6,420,036 and/or 7,274,501, which are hereby incorporated herein by reference in their entireties.

Optionally, the display or displays and any associated user inputs may be associated with various accessories or systems, such as, for example, a tire pressure monitoring system or a passenger air bag status or a garage door opening system or a telematics system or any other accessory or system of the mirror assembly or of the vehicle or of an accessory module or console of the vehicle, such as an accessory module or console of the types described in U.S. Pat. Nos. 7,289,037; 6,877,888; 6,824,281; 6,690,268; 6,672,744; 6,386,742 and/or 6,124,886, and/or U.S. Publication No. US-2006-0050018, which are hereby incorporated herein by reference in their entireties.

Changes and modifications in the specifically described embodiments can be carried out without departing from the principles of the invention, which is intended to be limited only by the scope of the appended claims, as interpreted according to the principles of patent law including the doctrine of equivalents.

1. A vision system for a vehicle, said vision system comprising:
a camera configured to be disposed at a vehicle so as to have a field of view exterior of the vehicle;
wherein said camera comprises a pixelated imaging array having a plurality of photosensing elements;
wherein said camera has a lens assembly having at least one optic element; and
wherein one of (i) said at least one optic element comprises graphene, (ii) said at least one optic element has a graphene coating or trace at a surface thereof, (iii) said at least one optic element has a transparent shield disposed thereat and said transparent shield comprises graphene or a graphene coating or trace and (iv) said at least one optic element has a replaceable protective element disposed thereat and said replaceable protective element comprises graphene or a graphene coating or trace.

2. The vision system of claim 1, wherein said at least one optic element comprises an outermost optic element of said lens assembly and wherein, when said camera is disposed at the vehicle, said outermost optic element is exposed at an exterior portion of the vehicle.

3. The vision system of claim 2, wherein one of (i) said outermost optic element comprises graphene and (ii) said outermost optic element has a transparent shield disposed thereat and comprising graphene and (iii) said outermost optic element has a replaceable protective element disposed thereat and comprising graphene.

4. The vision system of claim 2, wherein one of (i) said outermost optic element has a graphene coating or trace at a surface thereof and (ii) said outermost optic element has a transparent shield disposed thereat and comprising a graphene coating or trace at a surface thereof and (iii) said outermost optic element has a replaceable protective element disposed thereat and comprising a graphene coating or trace at a surface thereof.

5. The vision system of claim 4, wherein said graphene coating or trace is electrically connected to a power source of the vehicle and is energizable by the power source to heat the surface of one of (i) said outermost optic element, (ii) said transparent shield and (iii) said replaceable protective element.

6. The vision system of claim 1, wherein one of (i) said at least one optic element comprises graphene, (ii) said at least one optic element has a transparent shield disposed thereat and comprising graphene and (iii) said at least one optic element has a replaceable protective element disposed thereat and comprising graphene.

7. The vision system of claim 1, wherein (i) said at least one optic element has a graphene coating or trace at a surface thereof and (ii) said at least one optic element has a transparent shield comprising a graphene coating or trace at a surface thereof and (iii) said at least one optic element has a replaceable protective element comprising a graphene coating or trace at a surface thereof.

8. The vision system of claim 7, wherein said graphene coating or trace is electrically connected to a power source of the vehicle and is energizable by the power source to heat the surface of said at least one optic element.

9. The vision system of claim 1, wherein said at least one optic element has a replaceable protective element disposed thereat and wherein said replaceable protective element comprises graphene or a graphene coating or trace, and wherein said replaceable protective element is removably disposed at said at least one optic element, and wherein, when said replaceable protective element is disposed at said at least one optic element, electrical leads of said replaceable protective element electrically connect said graphene or graphene coating or trace to electrical leads at said at least one optic element.

10. A glass or polymeric substrate suitable for use in a vehicle, said glass or polymeric substrate comprising:
a graphene trace disposed at or in said glass or polymeric substrate; and
wherein said graphene trace is electrically connected to a power source of the vehicle and is energizable by the power source to heat said glass or polymeric substrate.

11. The glass or polymeric substrate of claim 10, wherein said glass or polymeric substrate comprises a transparent glass substrate of a window for the vehicle.

12. The glass or polymeric substrate of claim 11, wherein the window comprises a windshield of the vehicle and wherein said graphene trace is disposed at a region of the windshield that is located in front of a forward viewing camera of the vehicle, and wherein said forward viewing camera views through said graphene trace at said region of the windshield and through the windshield.

13. The glass or polymeric substrate of claim 10, wherein said glass or polymeric substrate comprises a replaceable protective element removably disposed at a glass window panel for the vehicle.

14. The glass or polymeric substrate of claim 13, wherein, when said replaceable protective element is disposed at the glass window panel of the vehicle, electrical leads of said replaceable protective element electrically connect said graphene trace to electrical leads at the glass window panel for the vehicle.

15. The glass or polymeric substrate of claim 10, wherein said glass or polymeric substrate comprises a glass substrate of an exterior mirror assembly for the vehicle.

16. The glass or polymeric substrate of claim 10, wherein said glass or polymeric substrate comprises a replaceable protective element removably disposed at a mirror reflective element for the vehicle.

17. The glass or polymeric substrate of claim 16, wherein, when said replaceable protective element is disposed at the mirror reflective element of the vehicle, electrical leads of said replaceable protective element electrically connect said graphene trace to electrical leads at the mirror reflective element for the vehicle.

18. A replaceable protective element suitable for use at a glass or polymeric element of a vehicle, said replaceable protective element comprising:
a thin glass or polymeric substrate;
a graphene trace disposed at a surface of said thin glass or polymeric substrate;
wherein said graphene trace terminates at electrical contacts exposed at said thin glass or polymeric substrate; and
wherein said replaceable protective element is configured to removably attach at a glass or polymeric element of a vehicle and wherein, when said replaceable protective element is attached at the glass or polymeric element of the vehicle, said exposed electrical contacts electrically connect to electrical contacts at the glass or polymeric element to electrically connect said graphene trace to a power supply at the vehicle.

19. The replaceable protective element of claim 18, wherein said replaceable protective element is configured to removably attach at one of (i) a glass window of the vehicle, (ii) a camera lens assembly of the vehicle and (iii) a mirror reflective element of an exterior rearview mirror of the vehicle.

20. The replaceable protective element of claim 19, wherein said replaceable protective element is configured to removably attach at a region of a windshield of the vehicle that is in front of a forward viewing camera of the vehicle.
